(19) United States
(12) Patent Application Publication
(10) Pub. No.: US 2010/0308894 A1
(43) Pub. Date: Dec. 9, 2010

(54) MEDICAL ELECTRONIC APPARATUS AND CONTROLLING METHOD THEREOF

(75) Inventor: Yuichi Koyama, Kanagawa (JP)

Correspondence Address: SNR DENTON US LLP, P.O. BOX 061080, CHICAGO, IL, 60606-1080, US

(73) Assignee: Sony Corporation, Tokyo (JP)

(21) Appl. No.: 12/778,303

(22) Filed: May 12, 2010

(30) Foreign Application Priority Data
Jun. 3, 2009 (JP) 2009-133608

(51) Int. Cl. H03K 17/945

(52) U.S. Cl. 327/517

(57) ABSTRACT

A medical electronic apparatus includes an operation unit corresponding to a certain operation; a non-contact temperature sensor sensing, in a non-contact manner, an entry of an object, with a temperature in a particular temperature range, at a predetermined distance from the operation unit; and a control unit controlling execution of an operation corresponding to the operation unit based on a signal output when the non-contact temperature sensor senses the object with a temperature in the particular temperature range.

### BACKGROUND OF THE INVENTION

1. Field of the Invention

The present invention relates to a medical electronic apparatus and a controlling method thereof, and more particularly to a medical electronic apparatus having an interface that receives an operational instruction in a non-contact manner and a controlling method thereof.

2. Description of the Related Art

Many user interfaces for electronic apparatuses have operational buttons that are pressed directly. In this operation or control, when an operation button or the like is directly pressed, a switch or other circuit on a substrate senses the depression and sends a control signal to a control target.

A user interface with a touch panel is also used. An example of the touch panel is a resistance film touch panel, which is placed on an LCD (liquid crystal display), PDP (plasma display panel), or CRT (cathode ray tube) display unit. This type of touch panel includes two plates, each of which has a transparent conductive film on which a conductive film is placed. Insulating spacers are placed between the plates with their conductive film sides facing one another. Electrodes are formed on each conductive film, so pressing a point on one of the substrates makes electrical continuity between the substrates to output the coordinates of the point (see, for example, Japanese Unexamined Patent Application Publication No. 2009-037344 and Japanese Unexamined Patent Application Publication No. 2008-515583).

A user interface for three-dimensional images is also proposed. In this user interface, sensors are disposed around a three-dimensional image and the positional data (coordinates) of user' fingers are immediately sent to a computer for real time drawing processing (see, for example, International Publication 2007-018111).

### SUMMARY OF THE INVENTION

However, a user interface using depression of an operation button or a touch panel is not suited to medical electronic apparatuses which are used in sanitary conditions because the button or touch panel is directly operated by user's fingers. In addition, the system configuration of a user interface for three-dimensional images is complicated.

It is desirable to provide a technique for operating a medical electronic apparatus in a non-contact manner.

According to an embodiment of the present invention, there is provided a medical electronic apparatus including an operation unit corresponding to a certain operation; a non-contact temperature sensor sensing, in a non-contact manner, an entry of an object, with a temperature in a particular temperature range, at a predetermined distance from the operation unit; and a control unit controlling the execution of an operation corresponding to the operation unit based on a signal output when the non-contact temperature sensor senses the object with a temperature in the particular temperature range.

In the embodiment of the present invention, the non-contact temperature sensor senses an entry of an object such as operator's finger, with a temperature in a particular temperature range, at a predetermined distance from the operation unit and controls the execution of an operation. Accordingly, the operator can carry out a certain operation without directly touching the operation unit.

The medical electronic apparatus according to the embodiment of the present invention may be an apparatus connected to or built into a medical apparatus. The medical electronic apparatus according to the embodiment of the present invention is characterized by its user interface, so the operations received by the operation unit correspond to operations, instructions, and settings for medical apparatuses.

In the medical electronic apparatus according to the embodiment of the present invention, when the control unit receives, for a predetermined time period, a signal output when the non-contact temperature sensor senses an object with a temperature in a particular temperature range, the control unit controls the execution of the operation corresponding to the operation unit. This prevents another object for which the operation is not instructed from being sensed incorrectly.

When the medical electronic apparatus according to the embodiment of the present invention may have a plurality of operation units and a plurality of non-contact temperature sensors corresponding to the plurality of operation units so that the detection ranges of the plurality of non-contact temperature sensors do not mutually overlap. Accordingly, instructions for the plurality of operation units can be discriminated correctly.

According to the embodiment of the present invention, there is provided a method of controlling a medical electronic apparatus including the steps of sensing, in a non-contact manner, an entry of an object, with a temperature in a particular temperature range, at a predetermined distance from the operation unit corresponding to a certain operation and controlling the execution of the operation corresponding to an operation unit based on a signal output when the object with a temperature within the particular temperature range is sensed.

In this type of invention, the non-contact temperature sensor senses an entry of an object such as operator's finger, with a temperature in a particular temperature range, at a predetermined distance from the operation unit to control the execution of the operation. This enables the operator to control a certain operation without directly touching the operation unit.

According to the embodiment of the present invention, it is possible to control an operation without directly touching the medical electronic apparatus.

### BRIEF DESCRIPTION OF THE DRAWINGS

FIG. 1 is a block diagram illustrating the configuration of a medical electronic apparatus according to an embodiment.

FIG. 2 is a diagram showing an example of application to an operation panel.

FIG. 3 is a diagram showing an example of application of the embodiment to a monitor used as the medical electronic apparatus.

FIG. 4 is a diagram showing an example of setting a focal length in light reception with a non-contact temperature sensor.

FIG. 5 is a diagram showing an example of control with the non-contact temperature sensor depending on the detection position of an object.

FIG. 6 is a flowchart illustrating the basic flow of the control method of the medical electronic apparatus according to the embodiment.

FIG. 7 is a flowchart showing an example of controlling the operation of the medical electronic apparatus according to the embodiment depending on distance.

### DESCRIPTION OF THE PREFERRED EMBODIMENTS

An embodiment according to the present invention will be described below in the following order.

1. Medical electronic apparatus (example of a block configuration, example of application to an operation panel, example of application to a monitor)

2. Example of the configuration of a non-contact sensor (example of setting a focal length, example of controlling an operation depending on distance)

3. Method of controlling a medical electronic apparatus (example of a basic control method, example of a method of controlling an operation depending on distance)

### <1. Medical Electronic Apparatus>

### [Block Configuration]

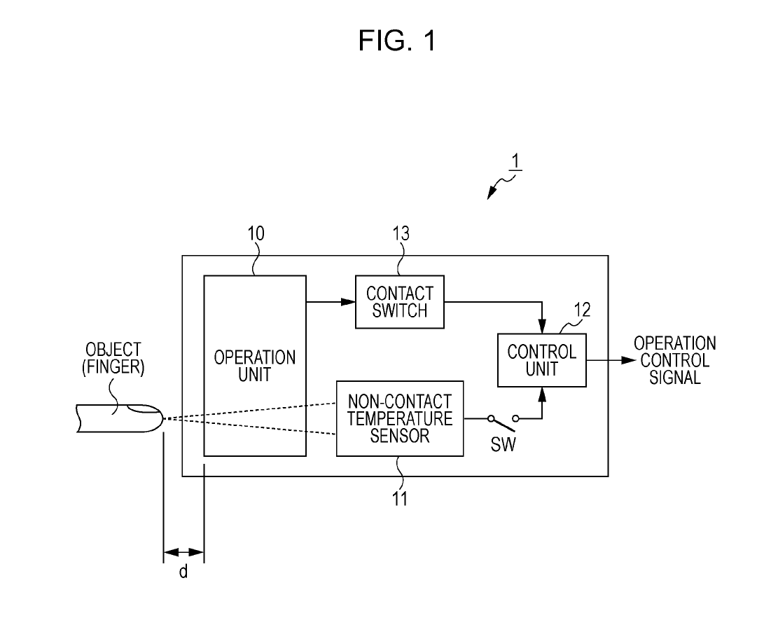

FIG. 1 is a block diagram illustrating the configuration of a medical electronic apparatus according to the embodiment. As shown in this figure, the medical electronic apparatus 1 according to the embodiment mainly includes an operation unit 10, a non-contact temperature sensor 11, a control unit 12, and, as necessary, a contact switch 13.

The operation unit 10 is a button corresponding to a certain operation of the medical electronic apparatus 1. Only one operation unit 10 is shown in FIG. 1 because this figure indicates the basic configuration, but a plurality of operation units 10 corresponding to a plurality of operations are actually provided.

The non-contact temperature sensor 11 senses, in a non-contact manner, an entry of an object, with a temperature in a particular temperature range, at a predetermined distance from the operation unit 10. Specifically, the non-contact temperature sensor 11 is an infrared sensor, which receives infrared rays of predetermined wavelengths and converts them into temperature information. The non-contact temperature sensor 11 according to the present embodiment senses the temperature (the amount of infrared ray emission) of an object located at a predetermined distance. When the object to be sensed is a finger, the predetermined temperature range is determined according to the surface temperature of the finger corresponding to the body temperature.

In the present embodiment, before the non-contact temperature sensor 11 senses the temperature of an object (such as a finger), the position at a predetermined distance d from the operation unit 10 is specified as a sensing position. For example, when an object such as a finger reaches the distance d from the operation unit 10, the surface temperature of the finger is sensed.

The non-contact temperature sensor 11 senses the temperature of the object at the distance d from the operation unit 10 and, if the temperature falls within a particular temperature range, outputs a detection signal. The non-contact temperature sensor 11 may sense the temperature of an object at the distance d from the operation unit 10 and output information about the temperature at all times. In this case, whether the temperature falls within the particular temperature range is determined by the control unit 12, which is disposed at a subsequent stage.

The control unit 12 outputs an operation control signal that controls the execution of the operation corresponding to the operation unit 10 based on the signal output when the non-contact temperature sensor 11 senses an object with a temperature in the particular temperature range. When the non-contact temperature sensor 11 outputs temperature information at all times, the control unit 12 outputs the operation control signal when the temperature falls within the particular temperature range, based on the temperature information output by the non-contact temperature sensor 11. When an apparatus at a subsequent stage receives this operation control signal, the operation corresponding to the operation unit 10 is performed.

The control unit 12 controls the execution of the operation corresponding to the operation unit 10 when the control unit 12 continuously receives, for a predetermined time period, the signal output when the non-contact temperature sensor 11 senses an object with a temperature in the particular temperature range or the temperature information that falls within the particular temperature range. The predetermined time period is, for example, one or two minutes in which a command for the operation unit 10 becomes clear. This prevents an operation error from occurring when an object (such as a finger) comes close to the operation unit 10 by mistake.

The medical electronic apparatus 1 according to the embodiment has the contact switch 13, which senses contact between an object (such as a finger) and the operation unit 10. The contact switch 13 is closed when the operation unit 10 is pressed by an object (such as a finger). An output signal cable of the contact switch 13 and an output signal cable of the non-contact temperature sensor 11 are routed to the control unit 12 in parallel.

Accordingly, in the medical electronic apparatus 1 according to the embodiment, a signal indicating the selection of the operation unit 10 is sent to the control unit 12 when an object (such as a finger) with a temperature in the particular temperature range comes close to the operation unit 10 or when an object makes contact with the operation unit 10. When a signal is sent by the non-contact temperature sensor 11 or the contact switch 13, the control unit 10 outputs the operation control signal that controls the execution of the operation corresponding to the operation unit 10.

In the medical electronic apparatus 1 according to the embodiment, a switch SW is disposed at an intermediate point on the output signal cable connected from the non-contact temperature sensor 11 to the control unit 12. When using only the contact switch 13 (without using the non-contact temperature sensor 11) to sense an operation on the operation unit 10, the switch SW is opened so that the signal from the non-contact temperature sensor 11 is not sent to the control unit 12. When using the non-contact temperature sensor 11, the switch SW is closed so that the signal from the non-contact temperature sensor 11 is sent to the control unit 12. The switch SW is disposed at an intermediate point on the output signal cable in FIG. 1, but the switch SW may be built into the control unit 12 or the signal from the non-contact temperature sensor 11 may be disabled by an internal circuit of the control unit 12.

The medical electronic apparatus 1 according to the embodiment is used especially in medical fields, so the surface of the operation unit 10 and the surface of the body are preferably antimicrobial-impregnated. The medical electronic apparatus 1 according to the embodiment is applicable to a user interface that receives an operation command by the operator and is achieved as the operation panel (user interface) for various medical apparatuses such as a printer, monitor, and image recording apparatus.

In the embodiment, only if an object, sensed by the non-contact temperature sensor 11, with a temperature in a particular temperature range comes close to the operation unit 10, it is possible to control the operation of the apparatus without directly touching it. If the particular temperature range is set to the temperature of the surface a finger or a gloved finger, the operator can carry out a desired operation by simply moving his finger toward the operation unit 10 without directly touching it. In the present embodiment, the non-contact temperature sensor 11 can be used to achieve a non-contact user interface even in a simple configuration.

The temperature range sensed by the non-contact temperature sensor 11 may be changed by the user. For example, the user may select a desired temperature range from a plurality of temperature ranges prepared in advance. In addition, it is possible to prepare a temperature range setting mode for setting a certain temperature range centered on the temperature sensed by moving an object (for example, a finger) to be sensed toward the operation unit 10.

### [Example of Application to an Operation Panel]

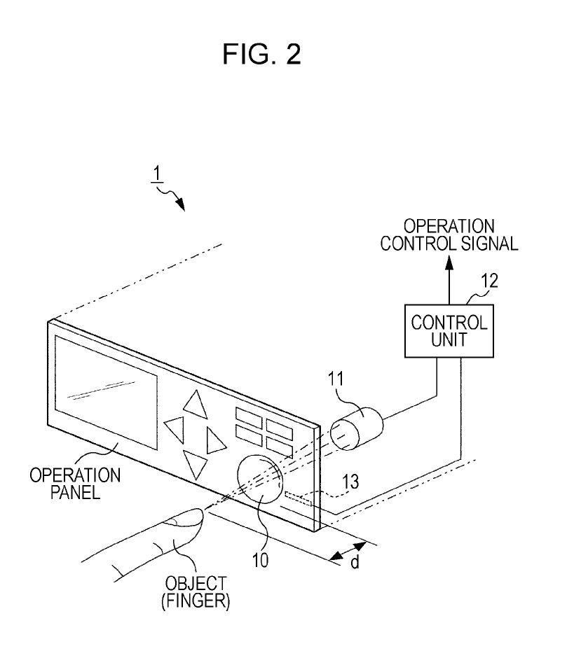

FIG. 2 is a diagram showing an example of application to an operation panel. FIG. 2 shows an example of applying the configuration according to the embodiment to the operation panel of the medical electronic apparatus 1. For example, in application to a printer used in medical fields, if the operation unit 10 is assumed to be a determination button for printing, the operation unit 10 is used to start printing in a non-contact manner. Specifically, when an image taken by a camera for treatment (for example, an endoscope camera) is printed during operation of the camera, the operation unit 10 can be used to perform printing without directly touching the print start button of the printer.

A monitor and various function selection buttons are disposed on the operation panel of the medical electronic apparatus 1. These buttons are disposed on the surface of the operation panel. For example, up arrow, down arrow, left arrow, and right arrow buttons, which are used for selection in various settings, function selection buttons, and the determination button (operation unit 10) are disposed. These buttons are mounted on the keyboard switch panel molded integrally with a button-shaped depress unit on a plain substrate via a skirt-like elastic deformable part. The buttons are covered with a front panel or cabinet front panel (not shown) to configure the operation panel. The contact switch 13 is disposed on the operation unit 10, which corresponds to the determination button on the keyboard switch panel. Direct depression of the operation unit 10 sends a signal indicating selection to the control unit 12.

The non-contact sensor 11 corresponds to the operation unit 10. The non-contact sensor 11 is disposed on the back of the operation panel, but it may be disposed on the keyboard switch panel on which the contact switch 13 is disposed.

The non-contact temperature sensor 11 senses the temperature of an object at the distance d from the surface of the operation panel on which the operation unit 10 is disposed. The non-contact sensor 11 is, for example, a sensor that senses infrared rays and converts them into temperature information. Accordingly, materials that do not block infrared rays are used for the operation panel, the operation unit 10, and a substrate on the back of the operation panel. When materials that block infrared rays are used, however, it is necessary to provide holes so that infrared rays can reach the non-contact temperature sensor 11.

The non-contact temperature sensor 11 senses the temperature at the distance d where focus is achieved in reception of infrared rays. In the present embodiment, it suffices that the finger temperature corresponding to the body temperature (for example, 35° C. to 37° C.) falls within a predetermined temperature range, so a non-contact temperature sensor, the particular temperature range of which is between 0° C. and 50° C. and the measurement error of which is within ±0.5° C., is used. In addition, when a small sensor is used, the panel can be thinned.

The non-contact temperature sensor 11 obtains the temperature of an object by taking the outside air temperature into account. The output signal of the non-contact temperature sensor 11 can be enabled or disabled by the control unit 12 and the non-contact temperature sensor 11 can be used concurrently with the contact switch 13 on the keyboard switch panel.

The output signal cables of the non-contact temperature sensor 11 and the contact switch 13 are connected in parallel to the control unit 12 and the output signals are sent to the control unit 12 separately.

### [Description of Operation]

When using the operation panel of the medical electronic apparatus 1 in FIG. 2, the operator moves an object with a temperature in a particular temperature range toward the operation unit 10. This object is assumed to be a finger of the operator. The non-contact temperature sensor 11 receives focused infrared rays from the finger coming close to the operation unit 10 on the operator panel at a distance (distance d) of several centimeters from the operation unit 10 of the operation panel and measures the temperature based on the received infrared rays.

The measured temperature information is sent to the control unit 12 via the output signal cable. The control unit 12 determines whether the object for which the temperature was measured by the non-contact temperature sensor 11 is a finger of the operator. In this determination, infrared rays radiated from the object at the constant distance d from the operation unit 10 are first received, and the temperature is measured when the amount of infrared ray reception reaches a constant value. Next, whether the object is the operation target is determined based on the temperature information obtained the object. If an object with a temperature in a constant temperature range is sensed and the temperature is held for a constant time period, the object is determined to be a finger of the operator and a detection signal is sent to the control unit 12.

When receiving the detection signal output from the non-contact temperature sensor 11, the control unit 12 outputs the operation control signal. Whether the object is a finger or not is determined by time period and the temperature measured by the non-contact temperature sensor 11 in the above example, but this determination may be performed by the control unit 12. In this case, the non-contact temperature sensor 11 sends the measured temperature information of the object at the distance d to the control unit 12. The control unit 12 determines whether the object is a finger or not depending on whether the temperature information sent from the non-contact temperature sensor 11 falls within the constant temperature range and the temperature is held for a constant time period. If the object is not determined to be a finger, the operation control signal is not output. If the object is determined to be a finger, the operation control signal is output.

### [Example of Application to a Monitor: Example of Application to a Plurality of Operation Units]

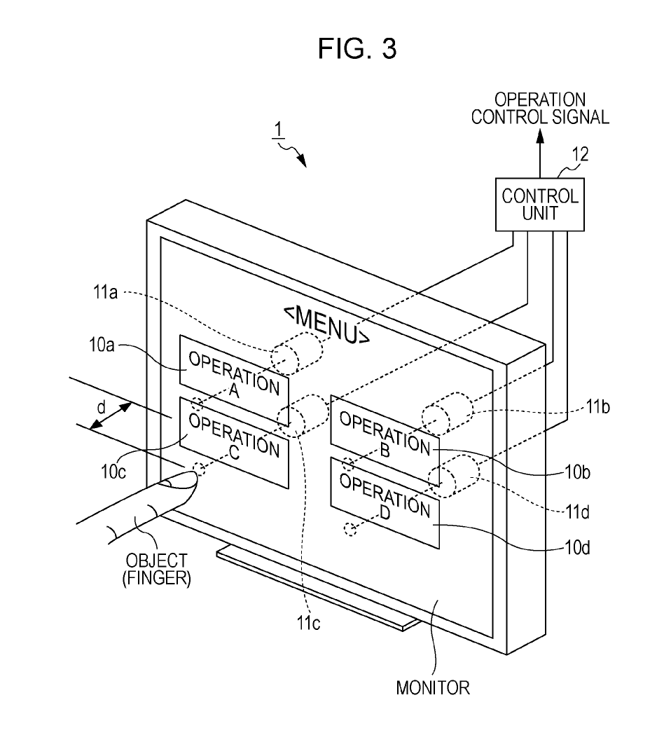

FIG. 3 is a diagram showing an example of application to a monitor used as the medical electronic apparatus. In this example, software buttons (icons) displayed on the monitor are the operation units. In the example shown in FIG. 3, four operation units 10a to 10d of operations A to D are displayed on the monitor as software buttons (icons). Different operations are assigned to the operation units 10a to 10d, respectively. The non-contact temperature sensors 11a to 11d correspond to the operation units 10a to 10d.

The non-contact temperature sensors 11a to 11d are placed on the back side of the display surface of the monitor of the cabinet. The non-contact temperature sensors 11a to 11d sense the temperatures of objects at the distance d from the surface of the monitor on which the operation units 10a to 10d are displayed. The non-contact temperature sensors 11a to 11d are, for example, sensors that sense infrared rays and convert them into temperature information.

The non-contact temperature sensors 11a to 11d sense the temperatures at distance d where focus is achieved in reception of infrared rays. The range of the focus of infrared rays is narrowed to prevent the sensing ranges of the non-contact temperature sensors 11a to 11d to overlap each other. This enables the operation units 10a to 10d to surely correspond to the non-contact temperature sensors 11a to 11d, respectively.

It suffices that the non-contact temperature sensors 11a to 11d according to the present embodiment cover the finger temperature corresponding to the body temperature (for example, 35° C. to 37° C.), so non-contact temperature sensors, the particular temperature range of which is between 0° C. and 50° C. and the measurement error of which is within ±0.5° C., are used. In addition, when small sensors are used, the monitor can be thinned. The non-contact temperature sensors 11a to 11d obtain the temperatures of objects by taking the outside air temperature into account.

The output signal cables of the non-contact temperature sensors 11a to 11d are connected to the control unit 12 and the signals are sent to the control unit 12. Based on the signals output from the non-contact temperature sensors 11a to 11d, the control unit 12 outputs the operation control signals depending on the operations associated with the corresponding operation units 10a to 10d.

### [Description of Operation]

When operating the monitor of the medical electronic apparatus 1 in FIG. 3, the operator moves an object with a temperature in a particular temperature range toward any of the operation units 10a to 10d. This object is assumed to be a finger of the operator. The non-contact temperature sensors 11a to 11d receive focused infrared rays from the finger coming close to any of the operation units 10a to 10d displayed on the monitor at a distance (distance d) of several centimeters from the operation units 10a to 10d and measure the temperature based on the received infrared rays.

The measured temperature information is sent to the control unit 12 via the output signal cable. The control unit 12 determines whether the object for which the temperature was measured by any of the non-contact temperature sensors 11a to 11d is a finger of the operator. In this determination, infrared rays radiated from the object that is at the constant distance d from the operation units 10a to 10d are first received, and the temperature is measured when the amount of infrared ray reception reaches a constant value. If an object with a temperature in a constant temperature range is sensed and the temperature is held for a constant time period, the object is determined to be a finger of the operator and the detection signal is sent to the control unit 12.

When receiving the detection signal output from one of the non-contact temperature sensors 11a to 11d, the control unit 12 outputs the operation control signal associated with one of the operations A to D corresponding to the non-contact temperature sensors 11a to 11d that output the signal.

Whether the object is a finger or not is determined by the time period and temperature measured by the non-contact temperature sensors 11a to 11d in the above example, but this determination may be performed by the control unit 12. In this case, the non-contact temperature sensors 11a to 11d send the measured temperature information of the object at the distance d to the control unit 12. The control unit 12 determines whether the object is a finger or not depending on whether the temperature information sent from the non-contact temperature sensor 11 falls within the constant temperature range and the temperature information is held for a constant time period. If the object is not determined to be a finger, the operation control signal is not output. If the object is determined to be a finger, the operation control signal is output.

In the present embodiment, the operation units 10a to 10d displayed on the monitor are software buttons (icons), so the correspondence between the operation units 10a to 10d and the operations can be switched. Accordingly, the control unit 12 outputs the operation control signals corresponding to the operation units 10a to 10d based on the correspondence between non-contact temperature sensors 11a to 11d that output sensing signals and their corresponding operation units 10a to 10d.

In the example shown in FIG. 3, the operation unit 10a is assigned the operation A, the operation unit 10b is assigned the operation B, the operation unit 10c is assigned the operation C, and the operation unit 10d is assigned the operation D. When an object (a finger in this case) reaches the distance d from operation unit 10c, the non-contact temperature sensor 11c measures the temperature of the object. If the measured temperature falls within a particular temperature range and is held for a constant time period, the object is determined to be a finger. This determination causes the non-contact temperature sensor 11c to output the detection signal to the control unit 12.

The control unit 12 references information about the current correspondence between the non-contact temperature sensors 11a to 11d and the operations A to D of the operation units 10a to 10d. The information about the correspondence is used by the program that displays the operation units (software buttons (icons)) and is set for each display state in which the operation units are displayed on the monitor.

In the example shown in FIG. 3, the operation unit 10a is assigned the operation A, the operation unit 10b is assigned the operation B, the operation unit 10c is assigned the operation C, and the operation unit 10d is assigned the operation D. Accordingly, when the signal is output from the non-contact temperature sensor 11c, the control unit 12 recognizes the operation C assigned to the operation unit 10c corresponding to the position of the non-contact temperature sensor 11c. This causes the control unit 12 to output an operation control signal for executing the operation C. The same description is applicable to the other operation units 10a, 10b, and 10d.

The current correspondence between the operation units 10a to 10d and the operations A to D switches depending on the display state of the monitor, so even if the signal is output from the non-contact temperature sensor 11c to the control unit when a finger comes close to the same operation unit 10c, the operation to be performed depends on the current assignment.

The four non-contact temperature sensors 11a to 11d corresponding to the four control units 10a to 10d are disposed in the example shown in FIG. 3, but more or less non-contact temperature sensors are applicable as well.

### <2. Example of Application of the Non-Contact Temperature Sensor>

### [Example of Setting the Focal Length]

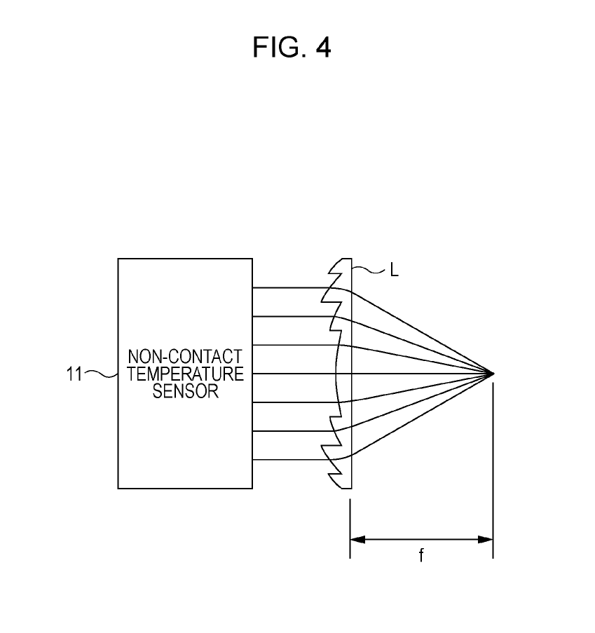

FIG. 4 is a diagram showing an example of setting a focal length in light reception with the non-contact temperature sensor. The non-contact temperature sensor 11 includes an infrared sensor, which receives infrared rays radiated externally. A lens L is attached to a photoreception surface of the non-contact temperature sensor 11. The lens L is, for example, a diffractive lens such as a Fresnel lens. The focal length f of the lens L indicates the conversing position at which infrared rays are sensed. This enables the sensing range of infrared rays sensed by the non-contact temperature sensor 11 to be narrowed.

The Fresnel lens used as the lens L is an example, so another lens can also be used. If a mechanism for adjusting the focal length f of the lens L is disposed, the sensing distance (distance d in FIG. 1) to the object can be adjusted.

### [Example of Controlling an Operation Depending on Distance]

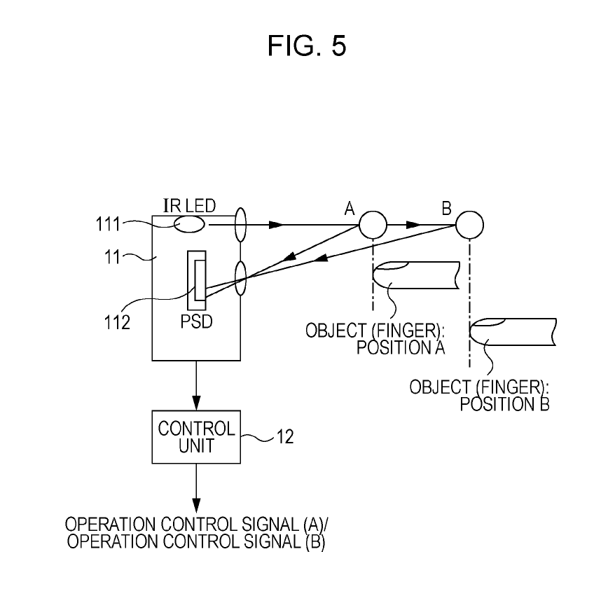

FIG. 5 is a diagram showing an example of control with a non-contact temperature sensor depending on the sensing position of an object. The non-contact temperature sensor 11 shown in FIG. 5 includes an infrared ray reception unit 111 and a position sensor 112. A sensing signal by the infrared ray reception unit 111 and a sensing signal by the position sensor 112 are output from the non-contact temperature sensor 11 to the control unit 12.

The infrared ray reception unit 111 senses infrared rays radiated from an object (for example, a finger) to obtain temperature information. The position sensor 112 senses the distance to the object using changes in the incident angle of infrared rays radiated from the object (such as a finger) that are caused when the object comes close to the position sensor 112.

In the example shown in FIG. 5, the object (for example, a finger) located in position A and the object located in position B are sensed. The non-contact temperature sensor 11 uses the infrared ray reception unit 111 to obtain temperature information and uses the position sensor 112 to obtain position information when the object (for example, a finger) is located in position A and when the object is located in position B.

The control unit 12 obtains the temperature information and position information output from the non-contact temperature sensor 11 and outputs the operation control signal depending on the position of the object (for example, a finger). That is, when the non-contact temperature sensor 11 outputs information indicating that the object (for example, a finger) is located in position A, if the measured temperature in the particular temperature range is held for a constant time period, the operation control signal (A) depending on position A is output. When the non-contact temperature sensor 11 outputs information indicating that the object (for example, a finger) is located in position B, if the measured temperature in the particular temperature range is held for a constant time period, the operation control signal (B) depending on position B is output.

Since the control unit 12 switches the control signal depending on the position of the object (for example, a finger) as described above, even if the object (for example, a finger) comes close to same operation unit, a different operation can be selected depending on the distance.

The control unit 12 receives the temperature information and position information from the non-contact temperature sensor 11 to determine the temperature and position in the above example, but the non-contact temperature sensor 11 may determine the temperature and position and may output the determination result to the control unit 12. In this case, the control unit 12 switches between the operation control signals (A) and (B) depending on the signal indicating the determination result output from the non-contact temperature sensor 11.

The operation is switched between the two object positions (position A and position B) are adopted as the position of the object in the above example, but the operation can also be switched between three or more positions.

If the non-contact temperature sensor 11 shown in FIG. 5 is applied to the plurality of non-contact temperature sensors 11a to 11d shown in FIG. 3, the operation can be switched by the movement in the depth direction in addition to the plane position of the object (for example, a finger). That is, the operation can be switched depending on three-dimensional positions.

### <Method of Controlling a Medical Electronic Apparatus>

### [Example of a Basic Control Method]

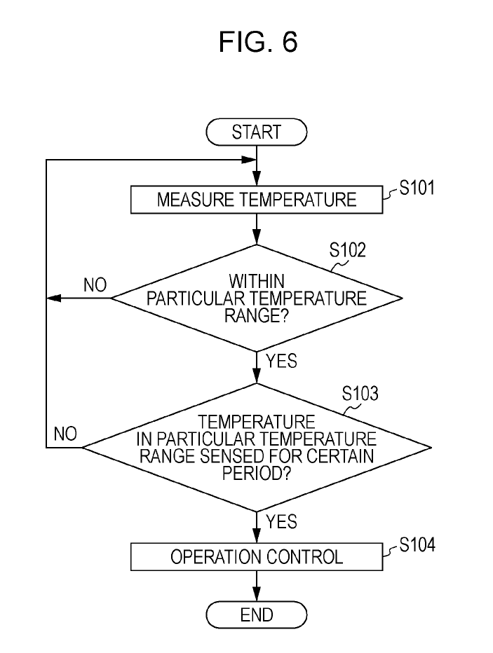

FIG. 6 is a flowchart illustrating the basic flow of the control method of the medical electronic apparatus according to the embodiment. In the following descriptions, the reference numerals not shown in FIG. 6 are indicated in FIG. 1. First, when the object (for example, a finger) comes close to the operation unit 10, the non-contact temperature sensors 11 measures the temperature (step S101). The non-contact temperature sensors 11 may measure the temperature at all times or may measure the temperature only when distance to the object is a predetermined distance d.

Next, whether the measured temperature falls within the particular temperature range is determined (step S102). This determination may be performed by the non-contact temperature sensors 11 or the control unit 12. If the measured temperature falls outside the particular temperature range, the processing returns to step S101. If the measured temperature falls within the particular temperature range, whether the temperature is held in the particular temperature range for a constant time period is determined (step S103). This determination may be performed by the non-contact temperature sensors 11 or the control unit 12.

If the temperature is not held in the particular temperature range for a constant time period (that is, the temperature deviates from the particular temperature range before the constant time period elapses), the processing returns to step S101. If the temperature is held in the particular temperature range for a constant time period, the control unit 12 outputs operation control signal (step S104).

Since operation control is performed only when the constant time period elapses in a particular temperature range as described above, selection of the operation unit 10 by the object (for example, a finger) is surely determined, thereby enabling correct operation control.

### [Example of Controlling Operation Depending on Distance]

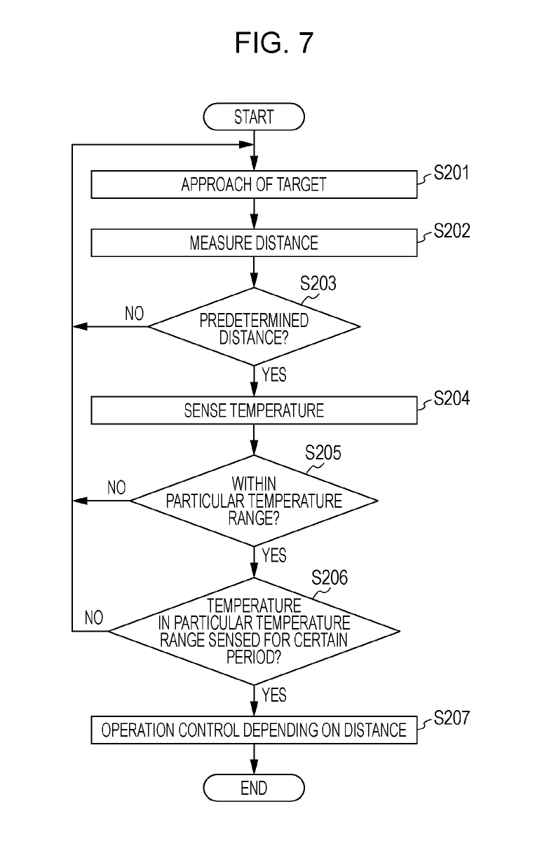

FIG. 7 is a flowchart showing an example of controlling the operation of the medical electronic apparatus according to the embodiment depending on distance. In the following descriptions, the reference numerals not shown in FIG. 7 are indicated in FIG. 1.

First, when a target (for example, a finger) comes close to the operation unit 10 (step S201), the distance to the target is measured (step S202). The distance is measured by the position sensor 112 shown in FIG. 5.

Next, whether the measured distance to the target equals a preset distance is determined (step S203). This determination may be performed by the non-contact temperature sensors 11 or the control unit 12. When the measured distance to the target does not equal the preset distance, the processing returns to step S201. When the measured distance to the target equals the preset distance, the non-contact temperature sensors 11 measures the temperature of the target (step S204).

Next, whether the measured temperature falls within the particular temperature range is determined (step S205). This determination may be performed by the non-contact temperature sensors 11 or the control unit 12. If the measured temperature falls outside the particular temperature range, the processing returns to step S201. If the measured temperature falls within the particular temperature range, whether the temperature is held in the particular temperature range for a constant time period is determined (step S206). This determination may be performed by the non-contact temperature sensors 11 or the control unit 12.

If the temperature is not held in the particular temperature range for a constant time period (that is, the temperature deviates from the particular temperature range before the constant time period elapses), the processing returns to step S201. If the temperature is held in the particular temperature range for a constant time period, the control unit 12 outputs operation control signal that depends on the distance measured in step S202 (step S206).

Since operation control is performed only when the constant time period elapses in a particular temperature range as described above, selection of the operation unit by the object (for example, a finger) is surely determined, thereby enabling correct operation control. In addition, since a different operation control signal is output depending on the distance from the object (for example, a finger) to the operation unit 10, an operation that depends on the distance can be instructed.

As described above, if the medical electronic apparatus has a user interface operable without directly touching the operation unit 10, it is possible to provide a device suited to use in sanitary conditions. In addition, use of the non-contact temperature sensor 11 achieves apparatus control that can recognize substantially only human fingers even in a simple configuration.

The present application contains subject matter related to that disclosed in Japanese Priority Patent Application JP 2009-133608 filed in the Japan Patent Office on Jun. 3, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A medical electronic apparatus comprising:
an operation unit corresponding to a certain operation;
a non-contact temperature sensor sensing, in a non-contact manner, an entry of an object, with a temperature in a particular temperature range, at a predetermined distance from the operation unit; and
a control unit controlling the execution of an operation corresponding to the operation unit based on a signal output when the non-contact temperature sensor senses the object with a temperature in the particular temperature range.

2. The medical electronic apparatus of claim 1, wherein the control unit controls the execution of the operation corresponding to the operation unit when the control unit receives the signal output by the non-contact temperature sensor when the non-contact temperature sensor senses the object with a temperature in the particular temperature range for a preset time period or more.

3. The medical electronic apparatus of claim 1 or 2, further comprising a contact sensor that senses contact with the operation unit, wherein an output signal cable of the contact sensor and an output signal cable of the non-contact temperature sensor are connected in parallel to the control unit.

4. The medical electronic apparatus of any one of claims 1 to 3, wherein the non-contact temperature sensor has a distance sensing unit that senses a distance to the object and, the distance sensing unit outputs the signal to the control unit when the distance sensing unit senses that the distance to the object equals the predetermined distance.

5. The medical electronic apparatus of any one of claims 1 to 4, wherein the non-contact temperature sensor has a lens for setting the predetermined distance in order to sense infrared rays corresponding to the particular temperature range.

6. The medical electronic apparatus of any one of claims 1 to 5, wherein a plurality of operation units are disposed, the operation unit being one of the plurality of operation units, and a plurality of non-contact temperature sensors corresponding the plurality of operation units are disposed, the non-contact temperature sensor being one of the plurality of non-contact temperature sensors, so that sensing ranges of the plurality of non-contact temperature sensors do not mutually overlap.

7. A method of controlling a medical electronic apparatus, comprising the steps of:
sensing, in a non-contact manner, an object at a predetermined distance from an operation unit corresponding to a certain operation; and
controlling execution of an operation corresponding to the operation unit based on a signal output when the non-contact temperature sensor senses the object with a temperature in the particular temperature range.
